(19) United States
(12) Patent Application Publication
(10) Pub. No.: US 2026/0033093 A1
(43) Pub. Date: Jan. 29, 2026

(54) WINDOW PROTECTIVE FILM, DISPLAY DEVICE INCLUDING THE SAME, AND ELECTRONIC DEVICE INCLUDING THE SAME

(71) Applicant: Samsung Display Co., Ltd., Yongin-si (KR)

(72) Inventors: JUNG HO PARK, Yongin-si (KR); HANSOL KANG, Yongin-si (KR); INSEOK SEO, Yongin-si (KR); SEUNGHWAN CHUNG, Yongin-si (KR)

(21) Appl. No.: 19/178,374

(22) Filed: Apr. 14, 2025

(30) Foreign Application Priority Data
Jul. 29, 2024 (KR) 10-2024-0100317

(51) Int. Cl. H10H 29/80; G06F 1/16; H10H 29/85; H10H 29/855

(52) U.S. Cl. CPC H10H 29/842; G06F 1/1652; H10H 29/8508; H10H 29/855

(57) ABSTRACT

A window protective film includes: a shock absorbing layer including acrylic resin and having a modulus of about 300 MPa or less; a base layer located on the shock absorbing layer; and a hard coating layer located on the base layer.

### CROSS-REFERENCE TO RELATED APPLICATION

The present application claims priority to and benefits of Korean Patent Application No. 10-2024-0100317, filed on Jul. 29, 2024, in the Korean Intellectual Property Office, the entire content of which is incorporated herein by reference.

### BACKGROUND

### 1. Field

One or more embodiments of the present disclosure relate to a window protective film and a display device including the same. For example, one or more embodiments of the present disclosure relate to the window protective film designed to protect a window layer of the display device and the display device including the same.

### 2. Description of the Related Art

As information technology progresses, display devices, which are communication media between users and information, are becoming essential. Accordingly, the use of display devices such as a liquid crystal display device, an organic light emitting display device, a plasma display device, and/or the like is increasing.

Recently, flexible display devices capable of being transformed into one or more suitable shapes have been developed. Unlike rigid, flat panel displays, the flexible display devices can be folded, bent, or rolled like paper, enhancing portability and user convenience. Among these flexible display devices, foldable display devices have been in the spotlight due to their ability to be repeatedly folded and unfolded.

### SUMMARY

One or more aspects of embodiments of the present disclosure are directed toward a window protective film with enhanced (e.g., improved) impact resistance.

One or more aspects of embodiments of the present disclosure are directed toward a display device including the window protective film.

Additional aspects will be set forth in part in the description which follows and, in part, will be apparent from the description, or may be learned by practice of the presented embodiments.

According to one or more embodiments of the present disclosure, a window protective film includes a shock absorbing layer including an acrylic resin and having a modulus of about 300 MPa or less, a base layer on (e.g., located on) the shock absorbing layer, and a hard coating layer on (e.g., located on) the base layer.

In one or more embodiments, the modulus of the shock absorbing layer may be in a range of about 1 MPa to about 200 MPa at room temperature.

In one or more embodiments, the modulus of the shock absorbing layer may be in a range of about 1 MPa to about 300 MPa at about −20° C.

In one or more embodiments, a thickness of the shock absorbing layer may be in a range of about 20 micrometers (μm) to about 30 micrometers (μm).

In one or more embodiments, the shock absorbing layer may be coated on a lower layer or a lower surface of the base layer and arranged directly on the lower layer or the lower surface of the base layer.

In one or more embodiments, a modulus of the base layer may be in a range of about 5,000 MPa to about 6,000 MPa.

In one or more embodiments, the base layer may include polyethylene terephthalate (PET).

According to one or more embodiments of the present disclosure, a display device includes a display panel including a display area where a plurality of pixels are arranged, a window layer on (e.g., located on) the display panel, and a window protective film on (e.g., located on) the window layer and including: a shock absorbing layer including an acrylic resin and having a modulus of about 300 MPa or less, a base layer on (e.g., located on) the shock absorbing layer, and a hard coating layer on (e.g., located on) the base layer.

In one or more embodiments, the modulus of the shock absorbing layer may be in a range of about 1 MPa to about 200 MPa at room temperature.

In one or more embodiments, the modulus of the shock absorbing layer may be in a range of about 1 MPa to about 300 MPa at about −20° C.

In one or more embodiments, a thickness of the shock absorbing layer may be in a range of about 20 micrometers (μm) to about 30 micrometers (μm).

In one or more embodiments, the shock absorbing layer may be coated on a lower layer or a lower surface of the base layer and arranged directly on the lower layer or the lower surface of the base layer.

In one or more embodiments, a modulus of the base layer may be in a range of about 5,000 MPa to about 6,000 MPa.

In one or more embodiments, the base layer may include polyethylene terephthalate (PET).

In one or more embodiments, the window layer may include ultra-thin glass (UTG).

In one or more embodiments, the display device may further include a first adhesive member attaching the window layer and the window protective film to each other and including a pressure-sensitive adhesive (PSA).

In one or more embodiments, a modulus of the first adhesive member may be in a range of about 0.2 MPa or less.

In one or more embodiments, the display device may further include a polarizing member between (e.g., located between) the display panel and the window layer and a second adhesive member attaching the polarizing member and the window layer to each other and including a pressure-sensitive adhesive.

In one or more embodiments, the display area may include a foldable area having a flexibility and a non-folding area adjacent to at least one side of the foldable area.

In one or more embodiments, the display device may further include a support plate on (e.g., located on) a first surface of the display panel. The window layer and the window protective film may be on (e.g., located on) a second surface of the display panel, the second surface being opposite to the first surface.

According to one or more embodiments of the present disclosure, an electronic device includes a display device including: a display panel including a display area where a plurality of pixels are arranged; a window layer on (e.g., located on) the display panel; and a window protective film on (e.g., located on) the window layer and including: a shock absorbing layer including an acrylic resin and having a modulus of about 300 MPa or less; a base layer on (e.g., located on) the shock absorbing layer; and a hard coating layer on (e.g., located on) the base layer, and a processor configured to control the display device with an image data signal and an input control signal.

A window protective film which protects a window layer according to one or more embodiments of the present disclosure may include a shock absorbing layer including an acrylic resin and having a modulus in a selected range, a base layer located on the shock absorbing layer, and a hard coating layer located on the base layer. Accordingly, the impact resistance of the window protective film may be improved and at the same time, the window protective film may have a relatively thin thickness. As a result, the folding characteristics of the display device may not deteriorate, and an overall thickness of the display device may be reduced, achieving a slimmer for the display device. For example, a window protective film, includes a shock-absorbing layer made of acrylic resin with a specific modulus range, a base layer on the shock-absorbing layer, and a hard coating layer on the base layer. This structure enhances the impact resistance of the window protective film while maintaining a relatively thin profile. Consequently, the folding characteristics of the display device are preserved, and the overall thickness of the display device is reduced, resulting in a slimmer design.

### BRIEF DESCRIPTION OF DRAWINGS

Illustrative, non-limiting embodiments will be more clearly understood from the following detailed description in conjunction with the accompanying drawings; however, they may be embodied in different forms and should not be construed as limited to example embodiments set forth herein. Rather, these embodiments are provided so that this disclosure will be thorough and complete, and will fully convey the scope of the example embodiments to those skilled in the art. The above and other aspects, features, and advantages of certain embodiments of the present disclosure will be more apparent from the following description taken in conjunction with the accompanying drawings.

FIG. 1 is a plan view showing a display device according to one or more embodiments of the present disclosure.

FIG. 2 and FIG. 3 are each a cross-sectional view showing the display device of FIG. 1 in a folded state according to one or more embodiments of the present disclosure.

FIG. 4 is a cross-sectional view taken along the line I-I′ of FIG. 1 according to one or more embodiments of the present disclosure.

FIG. 5 is a plan view showing a support plate of FIG. 4 according to one or more embodiments of the present disclosure.

FIG. 6 is a cross-sectional view showing a window protective film of FIG. 4 according to one or more embodiments of the present disclosure.

FIG. 7 is an enlarged cross-sectional view of area A of FIG. 4 according to one or more embodiments of the present disclosure.

FIG. 8 is a block diagram showing an electronic device according to one or more embodiments of the present disclosure.

FIG. 9 is a schematic diagram showing electronic devices according to one or more embodiments of the present disclosure.

### DETAILED DESCRIPTION

Hereinafter, a window protective film and a display device including the window protective film according to one or more embodiments of the present disclosure will be explained in more detail with reference to the accompanying drawings. The same reference numerals are used for the same or like components in the drawings, and redundant descriptions of the same or like components will not be provided for conciseness.

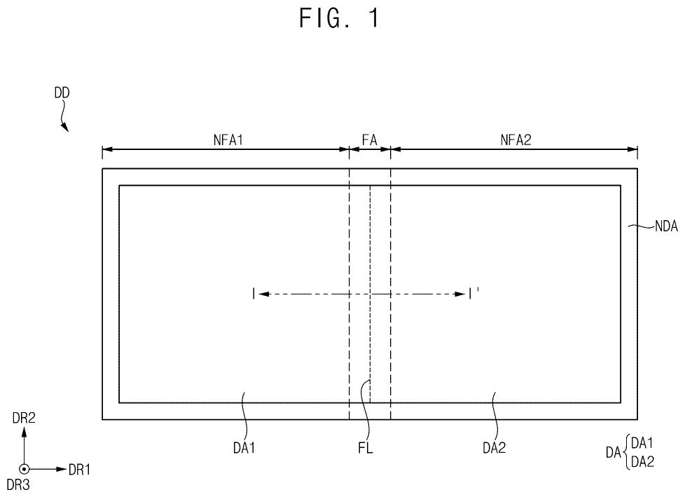

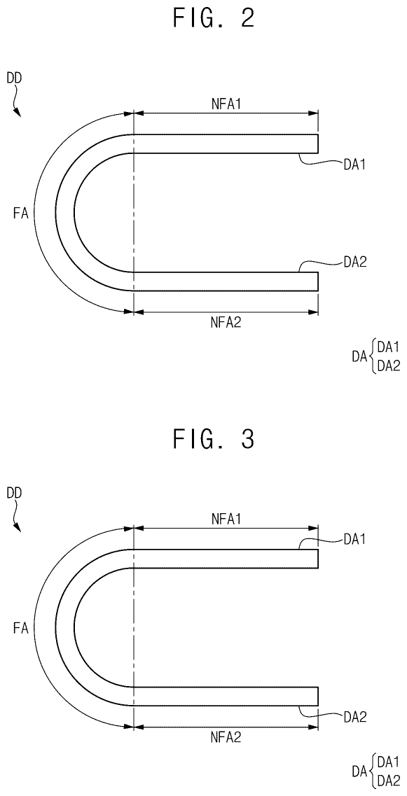

FIG. 1 is a plan view showing a display device according to one or more embodiments of the present disclosure. FIG. 2 and FIG. 3 are each a cross-sectional view showing the display device of FIG. 1 in a folded state according to one or more embodiments of the present disclosure.

Referring to FIGS. 1, 2, and 3, a display device DD according to one or more embodiments of the present disclosure may be divided into a display area DA and a non-display area NDA. The non-display area NDA may be located around the display area DA. For example, in one or more embodiments, the non-display area NDA may be around (e.g., surround) at least a portion of the display area DA. The display area DA may be an area that can display an image by generating light or adjusting the transmittance of light provided from an external light source. The non-display area NDA may be an area which does not display images.

At least a portion of the display device DD may be flexible and may be folded in a flexible portion (i.e., a foldable area FA). For example, in one or more embodiments, the display area DA may include a foldable area FA which may be bent by external force to fold the display device DD and a first non-folding area NFA1 and a second non-folding area NFA2 each adjacent to at least one side of the foldable area FA and not folded. For example, in one or more embodiments, the foldable area FA may have a folding line FL extending along a second direction DR2. Here, an area which does not fold is referred to as a non-folding area, but this is for convenience of explanation. The expression “non-folding” may include not only cases where it is rigid due to lack of flexibility, but also cases where the area is flexible but does not fold because it has a flexibility smaller than the foldable area FA. For example, areas that do not fold are referred to as “non-folding area,” which may include regions that are either rigid due to lack of flexibility or flexible but not folded due to having less flexibility than the foldable area FA.

The display area DA may be divided into a first display area DA1 and a second display area DA2. For example, in one or more embodiments, the first display area DA1 and the second display area DA2 may be adjacent to each other along the second direction DR2. The first display area DA1 and the second display area DA2 may be continuously connected to substantially form one display area DA. For example, in one or more embodiments, if (e.g., when) the display area DA is folded along the folding line FL, as shown in FIG. 2, the display device DD may have an in-folding structure so that the first display area DA1 and the second display area DA2 face each other. In one or more embodiments, if (e.g., when) the display area DA is folded along the folding line FL, as shown in FIG. 3, the display device DD may have an out-folding structure in which the first display area DA1 and the second display area DA2 are arranged (or located) on the outside.

In addition, in FIG. 1, the display device DD is shown as having one foldable area FA, but the display device DD according to one or more embodiments of the present disclosure is not limited to having one foldable area FA. For example, in one or more embodiments, the display device DD may be folded multiple times or may have a plurality of foldable areas to implement a rollable display device.

In this disclosure, a plane may be defined in a first direction DR1 and the second direction DR2. For example, the second direction DR2 may be normal (e.g., perpendicular) to the first direction DR1. In addition, a third direction DR3 may be normal (e.g., perpendicular) to the plane.

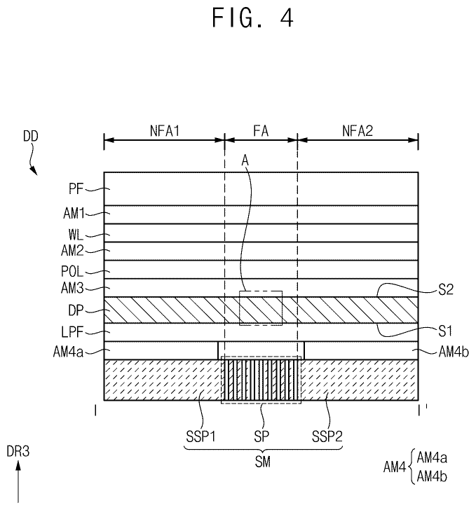

FIG. 4 is a cross-sectional view taken along the line I-I′ of FIG. 1 according to one or more embodiments of the present disclosure.

Referring to FIGS. 1 and 4, in one or more embodiments, the display device DD may include a display panel DP, a polarizing member POL, a window layer WL, a window protective film PF, first, second, third, and fourth adhesive members AM1, AM2, AM3, and AM4, a panel protective film LPF, and a support plate SM.

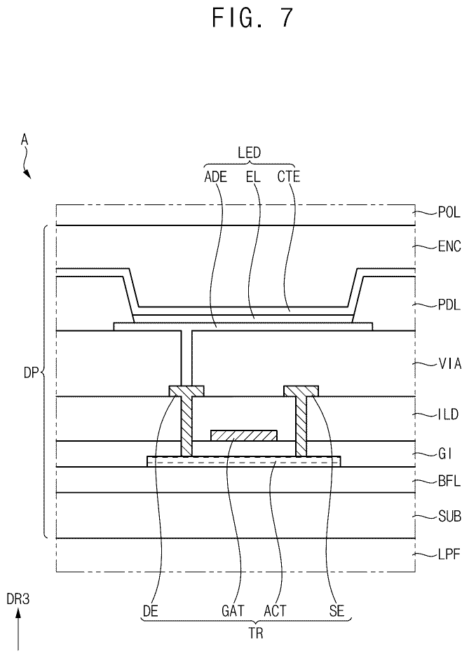

The polarizing member POL may be arranged (or located) on the display panel DP. The display panel DP may include a plurality of pixels that generate light. The polarizing member POL may block external light incident on the display panel DP from the outside. In one or more embodiments, the polarizing member POL may not be provided. In these embodiments, the display panel DP may include a color filter layer including a black matrix and color filters on an encapsulation layer (e.g., an encapsulation layer ENC of FIG. 7).

The window layer WL may be arranged (or located) on the polarizing member POL. The window layer WL may be arranged (or located) on a second surface S2 of the display panel DP. The window layer WL may protect the display panel DP. The window layer WL may have a transmission portion corresponding to the display area DA. The window layer WL may include a polymer material, a glass thin film, and/or the like to enable bending.

In one or more embodiments, the window layer WL may include ultra-thin glass (UTG). The ultra-thin glass may be strengthened and have a selected and/or suitable stress profile therein. The ultra ultra-thin glass may better prevent or reduce the occurrence of cracks, propagation of cracks, and breakage due to external impacts than before strengthening. In one or more embodiments, the ultra-thin glass may have one or more suitable stresses in each area through a strengthening process.

For example, in one or more embodiments, the ultra-thin glass of the window layer WL may be thin film glass which has been chemically strengthened to have strong strength. However, embodiments of the present disclosure are not necessarily limited to this, for example, in one or more embodiments, the ultra-thin glass of the window layer WL may be thin film glass which has been thermally strengthened.

If (e.g., when) a glass is composed of an ultra-thin film or a thin film, the glass may have flexible characteristics and may have characteristics which can be twisted, bent, folded, or rolled. For example, in one or more embodiments, the window layer WL may include glass such as soda lime glass, alkali aluminosilicate glass, borosilicate glass, lithium alumina silicate glass, and/or the like. These may be used alone or in combination with each other. However, embodiments of the present disclosure are not necessarily limited thereto, and the window layer WL may include one or more suitable types (kinds) of glass.

The window protective film PF may be arranged (or located) on the window layer WL. The window protective film PF may protect the window layer WL from external shock. In addition, the window protection film PF may prevent or reduce or minimize scratches on an upper surface of the window layer WL. The window protective film PF may perform at least one of the functions of preventing or reducing the window layer WL from scattering, absorbing shock, preventing or reducing scratches, preventing or reducing fingerprints, and preventing or reducing glare. A detailed description of the window protection film PF will be provided later.

The first adhesive member AM1 may be arranged (or located) between the window layer WL and the window protective film PF. The first adhesive member AM1 may attach the window layer WL and the window protective film PF to each other. For example, the first adhesive member AM1 may include an optical clear adhesive (OCA), a pressure-sensitive adhesive (PSA), a photocurable resin, or a thermosetting resin. In one or more embodiments, the first adhesive member AM1 may include a pressure-sensitive adhesive.

For example, the pressure-sensitive adhesive of the first adhesive member AM1 may include an acrylic resin, a silicone-based resin, a urethane-based resin, an epoxy-based resin, a rubber-based resin, a polyester-based resin, and/or the like. These may be used alone or in combination with each other.

In one or more embodiments, a modulus (i.e., storage modulus) of the first adhesive member AM1 may be in a range of about 0.2 MPa or less. If (e.g., when) the modulus of the first adhesive member AM1 satisfies the above range, bending reliability of the display device DD may be improved.

The second adhesive member AM2 may be arranged (or located) between the window layer WL and the polarizing member POL. The second adhesive member AM2 may attach the window layer WL and the polarizing member POL to each other. For example, the second adhesive member AM2 may include an optically clear adhesive, a pressure-sensitive adhesive, a photocurable resin, a thermosetting resin, and/or the like. These may be used alone or in combination with each other. In one or more embodiments, the second adhesive member AM2 may include a pressure-sensitive adhesive.

For example, the pressure-sensitive adhesive of the second adhesive member AM2 may include an acrylic resin, a silicone-based resin, a urethane-based resin, an epoxy-based resin, a rubber-based resin, a polyester-based resin, and/or the like. These may be used alone or in combination with each other.

In one or more embodiments, a modulus (i.e., storage modulus) of the second adhesive member AM2 may be in a range of about 0.2 MPa or less. If (e.g., when) the modulus of the second adhesive member AM2 satisfies the above range, bending reliability of the display device DD may be improved.

The third adhesive member AM3 may be arranged (or located) between the polarizing member POL and the display panel DP. The third adhesive member AM3 may attach the polarizing member POL and the display panel DP to each other. For example, the third adhesive member AM3 may include an optically clear adhesive, a pressure-sensitive adhesive, a photocurable resin, a thermosetting resin, and/or the like. These may be used alone or in combination with each other. In one or more embodiments, the third adhesive member AM3 may include a pressure-sensitive adhesive.

In one or more embodiments, a modulus (i.e., storage modulus) of the third adhesive member AM3 may be in a range of about 0.2 MPa or less. If (e.g., when) the modulus of the third adhesive member AM3 satisfies the above range, bending reliability of the display device DD may be improved.

For example, the pressure-sensitive adhesive of the third adhesive member AM3 may include an acrylic resin, a silicone-based resin, a urethane-based resin, an epoxy-based resin, a rubber-based resin, a polyester-based resin, and/or the like. These may be used alone or in combination with each other.

The panel protective film LPF may be arranged on a first surface S1 of the display panel DP, which is opposite to the second surface S2. The panel protective film LPF may overlap the foldable area FA and the non-folding areas NFA1 and NFA2. The panel protective film LPF may protect a lower surface (i.e., the first surface S1) of the display panel DP from external shock. The panel protective film LPF may include a flexible plastic material. For example, in one or more embodiments, the panel protective film LPF may include polyethylene terephthalate (PET). However, embodiments of the present disclosure are not necessarily limited thereto.

The support plate SM may be arranged (or located) under the panel protective film LPF. For example, in one or more embodiments, the support plate SM may be arranged (or located) to face the first surface S1 of the display panel DP. The support plate SM may serve to support the display panel DP. In one or more embodiments, the support plate SM may serve to assist in folding the display panel DP. In one or more embodiments, the support plate SM may prevent or reduce foreign substances from entering the display panel DP from the outside. In one or more embodiments, the support plate SM may radiate or disperse heat generated from the display panel DP.

A rigidity of the support plate SM may be greater than a rigidity of the display panel DP. Accordingly, the support plate SM may prevent or reduce the display panel DP from being deformed due to a user's external force, and/or the like.

In one or more embodiments, the support plate SM may include a first support portion SSP1, a second support portion SSP2, and a stretchable portion SP. The stretchable portion SP may be located between the first support portion SSP1 and the second support portion SSP2. The stretchable portion SP may overlap the foldable area FA, the first support portion SSP1 may overlap the first non-folding area NFA1, and the second support portion SSP2 may overlap the second non-folding area NFA2. Accordingly, the first and second support portions SSP1 and SSP2 may respectively support a portion of the display panel DP overlapping the first and second non-folding areas NFA1 and NFA2, and the stretchable portion SP may help the display panel DP be folded.

The stretchable portion SP may have stretchability in response to folding and unfolding of the display device DD. However, although it is shown in FIG. 4 that there is only one stretchable part SP, embodiments of the present disclosure are not necessarily limited thereto. For example, in one or more embodiments, the stretchable portion SP may be formed in plural pieces. A detailed description of the stretchable portion SP will be described in more detail later.

For example, in one or more embodiments, the support plate SM may include a metal, an alloy, and/or the like. In one or more embodiments, the support plate SM may include stainless steel (SUS), aluminum, a copper alloy, a magnesium alloy, a titanium alloy, and/or the like. These may be used alone or in combination with each other.

In one or more embodiments, the support plate SM may include glass or plastic (e.g., a polymer material). For example, in one or more embodiments, the support plate SM may include a carbon fiber reinforced plastic (CFRP), a glass fiber reinforced plastic (GFRP), and/or the like. However, embodiments of the present disclosure are not necessarily limited thereto, and the support plate SM may include one or more suitable materials.

The fourth adhesive member AM4 may be arranged (or located) between the panel protective film LPF and the support plate SM. The fourth adhesive member AM4 may attach the panel protective film LPF and the support plate SM to each other. In one or more embodiments, the fourth adhesive member AM4 may not overlap the foldable area FA but may overlap the non-folding areas NFA1 and NFA2. For example, in one or more embodiments, the fourth adhesive member AM4 may be divided into a first portion AM4a overlapping the first non-folding area NFA1 and a second portion AM4b overlapping the second non-folding area NFA2.

In one or more embodiments, the fourth adhesive member AM4 may include an optically clear adhesive, a pressure-sensitive adhesive, a photocurable resin, a thermosetting resin, and/or the like. These may be used alone or in combination with each other. In one or more embodiments, the fourth adhesive member AM4 may include a pressure-sensitive adhesive.

For example, the pressure-sensitive adhesive of the fourth adhesive member AM4 may include an acrylic resin, a silicone-based resin, a urethane-based resin, an epoxy-based resin, a rubber-based resin, a polyester-based resin, and/or the like. These may be used alone or in combination with each other.

In one or more embodiments, a modulus (i.e., storage modulus) of the fourth adhesive member AM4 may be in a range of about 0.2 MPa or less. If (e.g., when) the modulus of the fourth adhesive member AM4 satisfies the above range, bending reliability of the display device DD may be improved.

As described above, the display device DD according to one or more embodiments of the present disclosure can be folded or unfolded, so that each of the display panel DP, the polarizing member POL, the window layer WL, the window protective film PF, the first, second, third, and fourth adhesive members AM1, AM2, AM3, and AM4, the panel protective film LPF, and the support plate SM may each have flexibility.

In one or more embodiments, the display device DD may further include a lower structure arranged (or located) under the support plate SM. For example, the lower structure may further include at least one of an elastic member, a metal plate, a heat dissipation member, or a digitizer. However, embodiments of the present disclosure are not necessarily limited thereto.

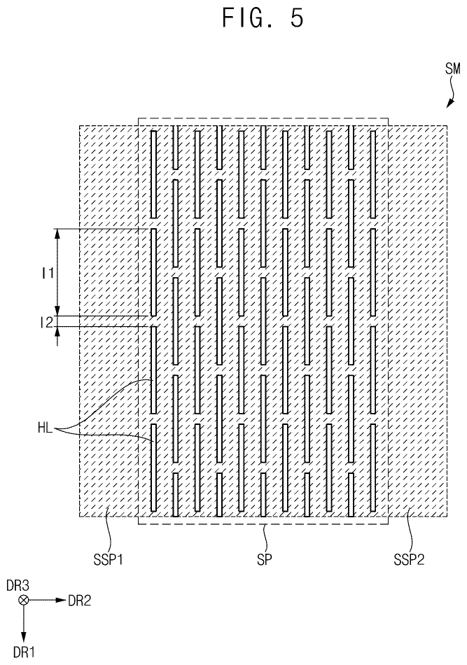

FIG. 5 is a plan view showing a support plate of FIG. 4 according to one or more embodiments of the present disclosure.

Referring to FIG. 5, as described above, the support plate SM may include the first support portion SSP1, the second support portion SSP2, and the stretchable portion SP. In one or more embodiments, a plurality of openings HL that are spaced and/or apart (e.g., spaced apart or separated) from each other may be defined in the stretchable portion SP. The plurality of openings HL may be formed by removing a portion of the stretchable portion SP through an etching process or a punching process.

Each of the plurality of openings HL may have a shape extending in the first direction DR1. For example, in one or more embodiments, a long axis of each of the plurality of openings HL may be parallel to the first direction DR1.

The plurality of openings HL may have the same planar shape. For example, in one or more embodiments, each of the plurality of openings HL may have a rectangular planar shape. However, embodiments of the present disclosure are not necessarily limited to this, and each of the plurality of openings HL may have one or more suitable planar shapes.

The plurality of openings HL may be arranged along the second direction DR2. For example, in one or more embodiments, each of the plurality of openings HL may have a selected length I1. In addition, the plurality of openings HL arranged in the same row may be spaced and/or apart (e.g., spaced apart or separated) by a selected distance I2. The plurality of openings HL arranged in the same row may be arranged in parallel with or staggered with the plurality of openings HL arranged in another adjacent row. However, embodiments of the present disclosure are not necessarily limited to this, and the arrangement of the plurality of openings HL may be changed in one or more suitable ways.

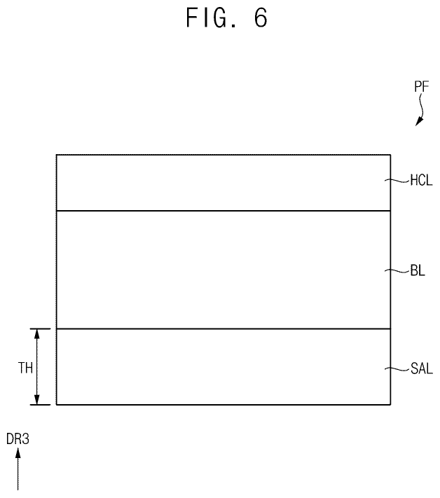

FIG. 6 is a cross-sectional view showing a window protective film of FIG. 4 according to one or more embodiments of the present disclosure.

Referring to FIG. 6, the window protective film PF may include a base layer BL and a hard coating layer HCL.

The base layer BL may include a flexible plastic material. For example, in one or more embodiments, the base layer BL may include polyethylene terephthalate (PET), polyimide (PI), polyacrylate (PAR), polyethersulfone (PS), polyetherimide (PEI), polycarbonate (PC), polyphenylene sulfide (PPS), polyethylene naphthalate (PEN), polymethyl methacrylate (PMMA), triacetylcellulose (TAC), cycloolefin, epoxy, and/or the like. These may be used alone or in combination with each other. In one or more embodiments, the base layer BL may include polyethylene terephthalate.

In one or more embodiments, a modulus (i.e., Young's modulus) of the base layer BL may be in the range of about 5,000 MPa to about 6,000 MPa. If (e.g., when) the modulus of the base layer BL satisfies the above range, the impact resistance of the window protective film PL may be improved.

The hard coating layer HCL may be arranged (or located) on the base layer BL. The hard coating layer HCL may reinforce the rigidity of the window layer WL and provide a flat upper surface. The hard coating layer HCL may include a curable resin. For example, in one or more embodiments, the curable resin may include an acrylate-based compound, a siloxane compound, a silsesquioxane compound, and/or the like. These may be used alone or in combination with each other. In one or more embodiments, the hard coating layer HCL may further include a functional layer such as an anti-fingerprint layer and/or an anti-static layer.

In one or more embodiments, the window protective film PF may further include a shock absorbing layer SAL arranged (or located) under the base layer BL. For example, in one or more embodiments, the shock absorbing layer SAL may be coated on a lower surface of the base layer BL facing the second surface S2 of the display panel DP and arranged directly on the lower surface of the base layer BL. The shock absorption layer SAL may improve the impact resistance of the window layer WL and the window protective film PF. In addition, due to the shock absorption layer SAL, a thickness of the window protective film PF may be formed relatively thin, and thus folding of the foldable area FA may be facilitated.

In one or more embodiments, the shock absorbing layer SAL may include an acrylic resin. For example, the acrylic resin may include polymethyl methacrylate, polyacrylic acid, and/or the like. These may be used alone or in combination with each other. However, embodiments of the present disclosure are not necessarily limited thereto, and the shock absorbing layer SAL may include one or more suitable types (kinds) of acrylic resin.

A modulus (i.e., storage modulus) of the shock absorbing layer SAL may have different ranges depending on temperature. In one or more embodiments, the modulus of the shock absorbing layer SAL may be in a range of about 1 MPa to about 200 MPa at room temperature (i.e., about 25° C.). If (e.g., when) the modulus of the shock absorbing layer SAL is less than about 1 MPa at room temperature, the impact resistance of the window protective film PF may be weakened. In this case, the display panel DP may be damaged due to external impact. In addition, if (e.g., when) the modulus of the shock absorbing layer SAL is less than about 1 MPa at room temperature, an overall thickness of the window protective film PF must be increased to prevent or reduce the impact resistance of the window protective film PF from weakening. In this case, the overall thickness of the display device DD increases, making it difficult to achieve a slimmer for the display device DD. If (e.g., when) the modulus of the shock absorbing layer SAL exceeds about 200 MPa at room temperature, the folding characteristics of the foldable area FA may deteriorate and reliability may deteriorate.

In one or more embodiments, the modulus of the shock absorbing layer SAL may be in the range of from about 1 MPa to about 300 MPa at a low temperature (e.g., about −20° C.). If (e.g., when) the modulus of the shock absorbing layer SAL is less than about 1 MPa at the low temperature, the impact resistance of the window protective film PF may be weakened. In this case, the display panel DP may be damaged due to external impact. In addition, if (e.g., when) the modulus of the shock absorbing layer SAL is less than about 1 MPa at the low temperature, the overall thickness of the window protective film PF must be increased to prevent or reduce the impact resistance of the window protective film PF from weakening. In this case, the overall thickness of the display device DD increases, making it difficult to achieve a slimmer for the display device DD. If (e.g., when) the modulus of the shock absorbing layer SAL exceeds about 300 MPa at the low temperature, the folding characteristics of the foldable area FA may deteriorate and reliability may deteriorate.

As a result, the modulus of the shock absorbing layer SAL may be in the range of about 300 MPa or less. In one or more embodiments, the modulus of the shock absorbing layer SAL may be in the range of about 1 MPa to about 300 MPa or less.

In one or more embodiments, a thickness TH of the shock absorbing layer SAL may be in the range of about 20 micrometers (μm) to about 30 micrometers (μm). If (e.g., when) the thickness TH of the shock absorbing layer SAL is less than about 20 micrometers (μm), the impact resistance of the window protective film PF may be weakened. If (e.g., when) the thickness TH of the shock absorbing layer SAL exceeds about 30 micrometers (μm), the folding characteristics of the foldable area FA may deteriorate.

As described above, the window protective film PF protecting the window layer WL according to one or more embodiments of the present disclosure may include the shock absorbing layer SAL including an acrylic resin and having the modulus in a selected range, the base layer BL arranged (or located) on the shock absorbing layer SAL, and the hard coating layer HCL arranged (or located) on the base layer BL. Accordingly, the impact resistance of the window protective film PF may be improved and at the same time, the window protective film PF may have a relatively thin thickness. In these embodiments, the folding characteristics of the display device DD may not deteriorate, and the overall thickness of the display device DD may be reduced, achieving a slimmer for the display device DD.

FIG. 7 is an enlarged cross-sectional view of area A of FIG. 4 according to one or more embodiments of the present disclosure. For example, FIG. 7 is an enlarged cross-sectional view of a portion of the display area DA of the display panel DP of FIG. 4 according to one or more embodiments of the present disclosure.

Referring to FIG. 7, the display panel DP may include a substrate SUB, a buffer layer BFL, a gate insulating layer GI, a transistor TR, an interlayer insulating layer ILD, a via insulating layer VIA, a pixel defining layer PDL, a light-emitting element LED, and an encapsulation layer ENC. Here, the transistor TR may include an active pattern ACT, a gate electrode GAT, a source electrode SE, and a drain electrode DE, and the light-emitting element LED may include an anode electrode ADE, a light-emitting layer EL, and a cathode electrode CTE.

The buffer layer BFL may be arranged (or located) on the substrate SUB. The buffer layer BFL may prevent or reduce metal atoms and/or impurities from diffusing from the substrate SUB to the transistor TR. In addition, the buffer layer BFL may improve the flatness of the surface of the substrate SUB if (e.g., when) the surface of the substrate SUB is not uniform. For example, in one or more embodiments, the buffer layer BFL may include an inorganic material such as silicon oxide (SiOₓ), silicon nitride (SiNₓ), silicon oxynitride (SiOₓN_{y}), and/or the like. These may be used alone or in combination with each other.

The active pattern ACT may be arranged (or located) on the buffer layer BFL. The active pattern ACT may include a metal oxide semiconductor, an inorganic semiconductor (e.g., amorphous silicon, poly silicon, and/or the like), or an organic semiconductor. The active pattern ACT may include a source region, a drain region, and a channel region located between the source region and the drain region.

The metal oxide semiconductor may include a binary compound (ABₓ), a ternary compound (ABₓC_{y}), a quaternary compound (ABₓC_{y}D_{z}), and/or the like containing indium (In), zinc (Zn), gallium (Ga), tin (Sn), titanium (Ti), aluminum (Al), hafnium (Hf), zirconium (Zr), magnesium (Mg), and/or the like. For example, the metal oxide semiconductor may include zinc oxide (ZnOₓ) (e.g., ZnO or ZnO₂), gallium oxide (GaOₓ), tin oxide (SnOₓ), indium oxide (InOₓ), indium gallium oxide (IGO), indium zinc oxide (IZO), indium tin oxide. (ITO), indium zinc tin oxide (IZTO), indium gallium zinc oxide (IGZO), and/or the like. These may be used alone or in combination with each other.

The gate insulating layer GI may be arranged (or located) on the buffer layer BFL. In one or more embodiments, the gate insulating layer GI may sufficiently cover the active pattern ACT and may have a substantially flat upper surface without creating a step around the active pattern ACT. In one or more embodiments, the gate insulating layer GI may cover the active pattern ACT and may be arranged along the profile of the active pattern ACT with a substantially uniform thickness. For example, the gate insulating layer GI may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), and/or the like. These may be used alone or in combination with each other.

The gate electrode GAT may be arranged (or located) on the gate insulating layer Gl. The gate electrode GAT may overlap the channel region of the active pattern ACT. The gate electrode GAT may include a metal, an alloy, a metal nitride, a conductive metal oxide, a transparent conductive material, and/or the like. Non-limiting examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and/or the like. Non-limiting examples of the conductive metal oxide may include indium tin oxide, indium zinc oxide, and/or the like. In addition, non-limiting examples of the metal nitride may include aluminum nitride (AlNₓ), tungsten nitride (WNₓ), chromium nitride (CrNₓ), and/or the like. These may be used alone or in combination with each other.

The interlayer insulating layer ILD may be arranged (or located) on the gate insulating layer GI. In one or more embodiments, the interlayer insulating layer ILD may sufficiently cover the gate electrode GAT and may have a substantially flat upper surface without creating a step around the gate electrode GAT. In one or more embodiments, the interlayer insulating layer ILD may cover the gate electrode GAT and may be arranged along a profile of the gate electrode GAT with a substantially uniform thickness. For example, the interlayer insulating layer ILD may include an inorganic material such as silicon oxide, silicon nitride, silicon carbide, silicon oxynitride, silicon oxycarbide, and/or the like. These may be used alone or in combination with each other.

The source electrode SE and the drain electrode DE may be arranged (or located) on the interlayer insulating layer ILD. The source electrode SE may be connected to the source region of the active pattern ACT through a contact hole penetrating a first portion of the gate insulating layer GI and the interlayer insulating layer ILD, and the drain electrode DE may be connected to the drain region of the active pattern ACT through a contact hole penetrating a second portion of the gate insulating layer GI and the interlayer insulating layer ILD. For example, each of the source electrode SE and the drain electrode DE may include a metal, an alloy, a metal nitride, a conductive metal oxide, a transparent conductive material, and/or the like. These may be used alone or in combination with each other.

Accordingly, the transistor TR including the active pattern ACT, the gate electrode GAT, the source electrode SE, and the drain electrode DE may be arranged (or located) in a display area (e.g., the display area DA of FIG. 1) on the substrate SUB.

The via insulating layer VIA may be arranged (or located) on the interlayer insulating layer ILD. In one or more embodiments, the via insulating layer VIA may sufficiently cover the source electrode SE and the drain electrode DE. The via insulating layer VIA may include an inorganic material or an organic material. In one or more embodiments, the via insulating layer VIA may include an organic material. For example, the via insulating layer VIA may include an organic material such as a phenolic resin, a polyacrylates resin, a polyimides rein, a polyamides resin, a siloxane resin, an epoxy resin, and/or the like. These may be used alone or in combination with each other.

The anode electrode ADE may be arranged (or located) on the via insulating layer VIA. The anode electrode ADE may be connected to the drain electrode DE (or the source electrode SE) through a contact hole penetrating the via insulating layer VIA. For example, the anode electrode ADE may include a metal, an alloy, a metal nitride, a conductive metal oxide, a transparent conductive material, and/or the like. These may be used alone or in combination with each other. In one or more embodiments, the anode electrode ADE may have a layered structure including ITO/Ag/ITO. However, embodiments of the present disclosure are not necessarily limited thereto.

The pixel defining layer PDL may be arranged (or located) on the via insulating layer VIA. The pixel defining layer PDL may cover an edge of the anode electrode ADE. In addition, an opening exposing at least a portion of an upper surface of the anode electrode ADE may be defined in the pixel defining layer PDL. For example, the pixel defining layer PDL may include an inorganic material or an organic material. In one or more embodiments, the pixel defining layer PDL may include an organic material such as an epoxy resin, a siloxane resin, and/or the like. These may be used alone or in combination with each other. In one or more embodiments, the pixel defining layer PDL may include an inorganic material and/or an organic material containing a light blocking material such as a black pigment, a black dye, and/or the like.

The light-emitting layer EL may be arranged (or located) on the anode electrode ADE. For example, the light-emitting layer EL may be arranged (or located) in the opening of the pixel defining layer PDL. The light-emitting layer EL may include a light emitting material which emits light of a selected color. For example, in one or more embodiments, the light-emitting layer EL may include a light emitting material which emits red light, green light, or blue light.

The cathode electrode CTE may be arranged (or located) on the pixel defining layer PDL and the light-emitting layer EL. For example, the cathode electrode CTE may include a metal, an alloy, a metal nitride, a conductive metal oxide, a transparent conductive material, and/or the like. These may be used alone or in combination with each other.

Accordingly, the light-emitting element LED including the anode electrode ADE, the light-emitting layer EL, and the cathode electrode CTE may be arranged (or located) in the display area on the substrate SUB. The light-emitting element LED may be electrically connected to the transistor TR. Thus, the light-emitting element LED may receive a driving signal from the transistor TR and generate light based on the driving signal.

The encapsulation layer ENC may be arranged (or located) on the cathode electrode CTE. The encapsulation layer ENC may protect the light-emitting element LED from foreign substances such as moisture and/or oxygen. In one or more embodiments, the encapsulation layer ENC may include at least one inorganic layer and at least one organic layer. In one or more embodiments, the encapsulation layer ENC may have a stacked structure of a first inorganic layer, an organic layer, and a second inorganic layer.

Hereinafter, the effects and benefit of the present disclosure according to Comparative Example and Embodiment will be described.

### Comparative Example 1 and Embodiment 1

In Comparative Example 1, a display device having substantially the same structure as the display device DD was manufactured except that the shock absorbing layer SAL of FIG. 6 was omitted.

In Embodiment 1, the display device DD was manufactured by sequentially attaching the polarizing member POL, the window layer WL, and the window protective film PF on the display panel DP. In this embodiment, the window layer WL was manufactured using ultra-thin glass, and the window protective film PF was manufactured by coating a curable resin on the upper surface of the base layer BL including PET to form the hard coating layer HCL, and coating an acrylic resin on the lower surface of the base layer BL to form the shock absorption layer SAL.

The modulus of the shock absorbing layer SAL was about 93 MPa at about 20° C., was about 240 MPa at a low temperature (i.e., about −20° C.), and the thickness was about 25 micrometers (μm).

A “ball drop” experiment was performed to evaluate impact resistance. For this purpose, a ball was dropped on the display device. The “ball drop” experiment measures a minimum height at which a defect in the display device occurs when the same ball is dropped on the display device. In the experiment, a mass of the ball was about 21.7 g and a diameter was about 17.5 mm.

TABLE 1

| | | Comparative | |
|---|---|---|---|
| | | Example 1 | Embodiment 1 |
| Drop height | Foldable area | 11 cm | 19 cm |
| | Non-folding | 14 cm | 19 cm |
| | area | | |

As a result, referring to Table 1, it can be confirmed that the minimum height at which a defect occurs in the foldable area of the display device satisfying Comparative Example 1 is about 11 cm, and the minimum height at which a defect occurs in the non-folding area of the display device is about 14 cm. In contrast, the minimum height at which a defect occurs in the foldable area FA of the display device DD satisfying Embodiment 1 is about 19 cm, and the minimum height at which a defect occurs in the non-folding area NFA1 and NFA2 of the display device DD is about 19 cm.

Through this, it can be confirmed that the display device DD satisfying Embodiment 1 has excellent or suitable impact resistance compared to the display device satisfying Comparative Example 1.

### Manufacturing Example 1, Manufacturing Example 2 and Manufacturing Example 3

In Manufacturing Example 1, a display device having substantially the same structure as the display device DD satisfying Embodiment 1 was manufactured, except that the display device includes a coating layer including an acrylic resin instead of the window protective film PF. Referring to Table 2, the modulus of the coating layer was about 620 MPa at room temperature (i.e., about 25° C.), was about 1,438 MPa at a low temperature (e.g., about −20° C.), and the thickness was about 70 micrometers (μm).

In Manufacturing Example 2, a display device having substantially the same structure as the display device DD satisfying Embodiment 1 was manufactured, except that the display device includes a coating layer including an acrylic resin instead of the window protective film PF. Referring to Table 2, the modulus of the coating layer was about 451 MPa at room temperature (i.e., about 25° C.), was about 1,010 MPa at a low temperature (e.g., about −20° C.), and the thickness was about 70 micrometers (μm).

In Manufacturing Example 3, a display device having substantially the same structure as the display device DD satisfying Embodiment 1 was manufactured, except that the display device includes a coating layer including an acrylic resin instead of the window protective film PF. Referring to Table 2, the modulus of the coating layer was about 82 MPa at room temperature (i.e., about 25° C.), was about 280 MPa at a low temperature (e.g., about −20° C.), and the thickness was about 70 micrometers (μm).

TABLE 2

| | | Manufacturing | | Manufacturing | | Manufacturing | |
|---|---|---|---|---|---|---|---|
| | | Example 1 | | Example 2 | | Example 3 | |
| modulus | low | 1,438 | MPa | 1,010 | MPa | 280 | MPa |
| | temperature | | | | | | |
| | room | 620 | MPa | 451 | MPa | 82 | MPa |
| | temperature | | | | | | |

### Experimental Example 1—Measurement of Folding Repulsion Force and Stress

For each of the display devices according to Manufacturing Example 1, Manufacturing Example 2, and Manufacturing Example 3, referring to Table 3, the folding repulsion force of the display device and the stress applied to the window layer of the display device were measured. To measure the folding repulsion force of the display device and the stress applied to the window layer, folding and unfolding of the display device was repeated tens to hundreds of thousands of times.

In Table 3, “folding repulsion force” is a relative value when the folding repulsion force of the display device satisfying Comparative Example 1 is set to 1, and “stress” is a relative value when the stress applied to the window layer satisfying Comparative Example 1 is set to 1.

### Experimental Example 2—“Pen Drop” Experiment

In the display devices according to Manufacturing Example 1, Manufacturing Example 2, and Manufacturing Example 3, in order to evaluate impact resistance, a “pen drop” experiment was performed to measure the stress (i.e., a first stress in Table 3) applied to the window layer of the display device. For this purpose, a pen was dropped from on the display device. The pens were dropped from the same height. At this time, the mass of the pen was about 5.8 g.

### Experimental Example 3—“Pen Pressure” Experiment

For each of the display devices according to Manufacturing Example 1, Manufacturing Example 2, and Manufacturing Example 3, in order to evaluate impact resistance, the display device was pressed with the pen and the stress (i.e., a second stress in Table 3) applied to the window layer of the display device was measured. The pens pressed the display device with the same pressure. In the experiment, the mass of the pen was about 5.8 g.

### Experimental Example 4—“Ball Drop” Experiment

For each of the display devices according to Manufacturing Examples 1, 2, and 3, in order to evaluate impact resistance, a “ball drop” experiment was performed to measure the strain of the display panel of the display device. The strain refers to the degree of deformation of an object due to external impact. The strain of the display panel may be defined as the ratio of the amount of deformation of the display panel due to impact compared to an initial state of the display panel. For this purpose, a ball was dropped from on the display device. The balls were dropped from the same height. In the experiment, the mass of the ball was about 21.7 g and the diameter was about 17.5 mm.

TABLE 3

| | Manufacturing | Manufacturing | Manufacturing |
|---|---|---|---|
| | Example 1 | Example 2 | Example 3 |
| Folding repulsion | 1.45 | 1.43 | 1.4 |
| force | | | |
| Stress of the window | 1.00 | 0.99 | 0.98 |
| layer | | | |
| First stress | 2,866 MPa | 2,824 MPa | 2,748 MPa |
| Second stress | 1,970 MPa | 1,928 MPa | 1,843 MPa |
| Strain | 1.08% | 1.05% | 0.95% |

As a result, it can be confirmed that the folding repulsion force and the stress applied to the window layer of the display device satisfying Manufacturing Example 3 are smaller than those of the display devices satisfying Manufacturing Examples 1 and 2. In addition, it can be confirmed that the first stress and the second stress applied to the window layer and the strain of the display panel satisfying Manufacturing Example 3 is smaller than the first stress and the second stress applied to the window layers and the strain of the display panels satisfying Manufacturing Example 1 and Manufacturing Example 2, respectively.

Through this, it can be confirmed that the display device satisfying Manufacturing Example 3 has excellent or suitable folding characteristics and impact resistance compared to the display devices satisfying Manufacturing Example 1 and Manufacturing Example 2.

As a result, if (e.g., when) the modulus of the shock absorbing layer SAL included in the window protective film PF of the display device DD according to one or more embodiments of the present disclosure is in the range of about 300 MPa or less at a low temperature (i.e., about −20° C.) and about 200 MPa or less at room temperature (i.e., about 25° C.), it can be confirmed that the display device DD has excellent or suitable folding characteristics and impact resistance compared to the case where the modulus of the shock absorbing layer SAL exceeds the upper limit of the above range.

To summarize, in Comparative Example 1, a display device similar to the display device DD was manufactured without the shock absorbing layer SAL.

In Embodiment 1, the display device DD was manufactured with a polarizing member POL, a window layer WL made of ultra-thin glass, and a window protective film PF including a shock absorbing layer SAL and a hard coating layer HCL. The modulus of the shock absorbing layer SAL was about 93 MPa at 20° C. and about 240 MPa at −20° C., with a thickness of about 25 μm. A “ball drop” experiment showed that the minimum height at which defects occurred was higher in Embodiment 1 compared to Comparative Example 1, indicating better impact resistance.

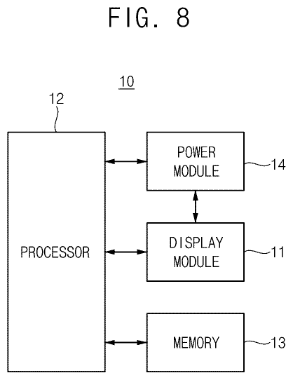

Further experiments with Manufacturing Examples 1, 2, and 3, which included different coating layers instead of the window protective film, demonstrated that the display device in Manufacturing Example 3 had superior folding characteristics and impact resistance. These examples followed the structure of Embodiment 1 but used a different type of coating layer made of acrylic resin. The results confirmed that a shock absorbing layer with a modulus of 300 MPa or less at low temperatures and 200 MPa or less at room temperature provides excellent folding characteristics and impact resistance. FIG. 8 is a block diagram showing an electronic device according to one or more embodiments of the present disclosure.

Referring to FIG. 8, an electronic device 10 may include a display module 11, a processor 12, a memory 13, and a power module 14.

A display device according to one or more embodiments (e.g., the display device DD of FIG. 1) may be applied to one or more suitable electronic devices 10. The electronic device 10 may include the display device described herein, and may further include modules or devices with additional functions other than the display device.

The processor 12 may include at least one of a central processing unit (CPU), an application processor (AP), a graphic processing unit (GPU), a communication processor (CP), an image signal processor (ISP), or a controller.

The memory 13 may store data information necessary for the operation of the processor 12 and/or the display module 11. When the processor 12 executes the application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module which converts the power supplied by the power supply module to generate power desired or required for the operation of the electronic device 10.

At least one of components of the electronic device 10 described above may be included in the display device according to the above-described embodiments. For example, some of the individual modules functionally included in one module may be included in the display device, and other portions may be provided separately from the display device. For example, the display device may include the display module 11, and the processor 12, the memory 13, and the power module 14 may be provided in the form of other devices within the electronic device 10 other than the display device. For example, the processor 12 may be configured to control the display device with the image data signal and the input control signal.

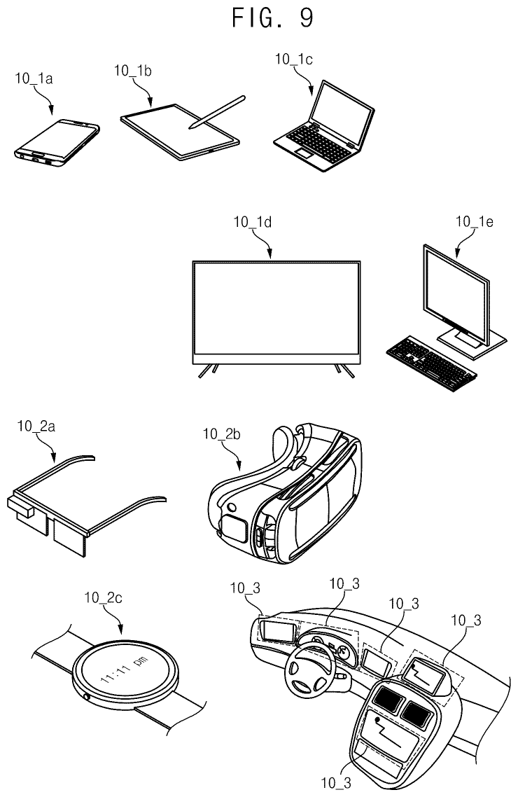

FIG. 9 illustrates schematic diagrams each showing an electronic device according to one or more embodiments of the present disclosure.

Referring to FIG. 9, one or more suitable electronic devices 10 to which one or more display devices according to one or more embodiments (e.g., the display device DD of FIG. 1) are applied may include not only image display electronic devices such as a smartphone 10_1a, a tablet PC 10_1b, a laptop 10_1c, a TV 10_1d, and a desktop monitor 10_1e, but also wearable electronic devices including display modules, such as smart glasses 10_2a, a head-mounted display 10_2b, and a smart watch 10_2c, automotive electronic devices 10_3 including display modules, such as a dashboard of a car, a center fascia, a Center Information Display (CID) arranged on a dashboard, and a room mirror display thereof, and/or the like.

The embodiments of present disclosure may be applied to one or more suitable electronic devices which can be equipped with a display device. For example, the embodiments of present disclosure may be applied to high-resolution smartphones, mobile phones, smart pads, smart watches, tablet PCs, vehicle navigation systems, televisions, computer monitors, laptops, and/or the like.

In the present disclosure, the term “modulus” as used herein may refer to the modulus of elasticity in tension, Young's modulus, or storage modulus.

In the context of the present application and unless otherwise defined, the terms “use,” “using,” and “used” may be considered synonymous with the terms “utilize,” “utilizing,” and “utilized,” respectively.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having”, or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the present disclosure, an expression that an element such as a layer, a region, a substrate, or a plate is placed “on” another element indicates not only embodiments in which the element is placed “directly on” the other element but also embodiments in which a further element may be interposed between the element and the other element. In contrast, if (e.g., when) an element is referred to as being “directly on” another element, there are no intervening element present therebetween. The terminology used herein is for the purpose of describing specific embodiments and is not intended to limit the disclosure. Throughout the disclosure, unless explicitly described to the contrary, the word “comprise/include/has” and variations such as “comprises/includes/have” or “comprising/including/having” will be understood to imply the inclusion of stated elements but not the exclusion of any other elements. “At least any one of A, B, and C,” “at least any one of A, B, or C,” “at least any one selected from among A, B, and C,” and “at least any one selected from the group consisting of A, B, and C” may be construed as each of A, B, and C or a (e.g., any suitable) combination of two or more of A, B, and C (for example, ABC, ABB, BC, and CC). As used herein, “and/or” or “or” may include one or more combinations of corresponding components.

It will be understood that, although the terms “first,” “second,” “third,” and so on may be used herein to describe one or more suitable elements, these elements are not limited by these terms. These terms are used to distinguish one element from another element. Thus, a first element described could also be termed as a second or third element without departing from the spirit and scope of the disclosure. As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure.

Spatially relative terms, such as “beneath,” “below,” “lower,” “above,” “upper,” and/or the like, may be used herein for descriptive purposes, and, thereby, to describe one element or feature's relationship to another element(s) or feature(s) as shown in the drawings. Spatially relative terms are intended to encompass different orientations of a device in use, operation, and/or manufacture in addition to the orientation depicted in the drawings. For example, if (e.g., when) the device in the drawings is turned upside down, elements described as “below” or “beneath” other elements or features would then be oriented “above” the other elements or features. Thus, in one or more embodiments, the example term “below” may encompass both (e.g., simultaneously) an orientation of above and below directions. Furthermore, the device may be otherwise oriented (e.g., rotated 90 degrees or at other orientations), and, as such, the spatially relative descriptors used herein interpreted accordingly.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The display device, the electronic device/apparatus, the display device-manufacturing apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The foregoing is illustrative of example embodiments and is not to be construed as limiting thereof. Although a few embodiments have been described, those skilled in the art will readily appreciate that many modifications are possible in one or more embodiments without materially departing from the teachings and advantages of the present disclosure. Accordingly, all such modifications are intended to be included within the scope of the present disclosure as defined in the appended claims. Therefore, it is to be understood that the foregoing is illustrative of embodiments and is not to be construed as limited to the specific embodiments disclosed, and that modifications to the disclosed embodiments, as well as one or more embodiments, are intended to be included within the scope of the appended claims and equivalents thereof.

What is claimed is:

1. A window protective film comprising:
a shock absorbing layer comprising an acrylic resin and having a modulus of about 300 MPa or less;
a base layer on the shock absorbing layer; and
a hard coating layer on the base layer.

2. The window protective film of claim 1, wherein the modulus of the shock absorbing layer is in a range of about 1 MPa to about 200 MPa at room temperature.

3. The window protective film of claim 1, wherein the modulus of the shock absorbing layer is in a range of about 1 MPa to about 300 MPa at about −20° C.

4. The window protective film of claim 1, wherein a thickness of the shock absorbing layer is in a range of about 20 micrometers to about 30 micrometers.

5. The window protective film of claim 1, wherein the shock absorbing layer is coated on a lower surface of the base layer and directly on the lower surface of the base layer.

6. The window protective film of claim 1, wherein a modulus of the base layer is in a range of about 5,000 MPa to about 6,000 MPa.

7. The window protective film of claim 1, wherein the base layer comprises polyethylene terephthalate.

8. A display device comprising:
a display panel comprising a display area where a plurality of pixels are arranged;
a window layer on the display panel; and
a window protective film on the window layer and comprising:
a shock absorbing layer comprising an acrylic resin and having a modulus of about 300 MPa or less;
a base layer on the shock absorbing layer; and
a hard coating layer on the base layer.

9. The display device of claim 8, wherein the modulus of the shock absorbing layer is in a range of about 1 MPa to about 200 MPa at room temperature.

10. The display device of claim 8, wherein the modulus of the shock absorbing layer is in a range of about 1 MPa to about 300 MPa at about −20° C.

11. The display device of claim 8, wherein a thickness of the shock absorbing layer is in a range of about 20 micrometers to about 30 micrometers.

12. The display device of claim 8, wherein the shock absorbing layer is coated on a lower surface of the base layer and directly on the lower surface of the base layer.

13. The display device of claim 8, wherein a modulus of the base layer is in a range of about 5,000 MPa to about 6,000 MPa.

14. The display device of claim 8, wherein the base layer comprises polyethylene terephthalate.

15. The display device of claim 8, wherein the window layer comprises ultra-thin glass.

16. The display device of claim 8, further comprising:
a first adhesive member attaching the window layer and the window protective film to each other and comprising a pressure-sensitive adhesive,
wherein a modulus of the first adhesive member is in a range of about 0.2 MPa or less.

17. The display device of claim 16, further comprising:
a polarizing member between the display panel and the window layer; and
a second adhesive member attaching the polarizing member and the window layer to each other and comprising a pressure-sensitive adhesive.

18. The display device of claim 8, wherein the display area comprises a foldable area having a flexibility and a non-folding area adjacent to at least one side of the foldable area.

19. The display device of claim 8, further comprising:
a support plate on a first surface of the display panel,
wherein the window layer and the window protective film are located on a second surface of the display panel, the second surface being opposite to the first surface.

20. An electronic device comprising:
a display device comprising:
display panel comprising a display area where a plurality of pixels are arranged;
a window layer on the display panel; and
a window protective film on the window layer and comprising:
a shock absorbing layer comprising an acrylic resin and having a modulus of about 300 MPa or less;
a base layer on the shock absorbing layer; and
a hard coating layer on the base layer; and
a processor configured to control the display device with an image data signal and an input control signal.
